(19) United States
(12) Patent Application Publication
(10) Pub. No.: US 2024/0289501 A1
(43) Pub. Date: Aug. 29, 2024

(54) DIGITAL DESIGN FOR AUTOMATION (DDFAUT) AUTOMATED ANALYSIS SYSTEM

(71) Applicant: Flex Ltd., Singapore (SG)

(72) Inventors: Jesus A. Tan, Fremont, CA (US); Murad M. Kurwa, San Jose, CA (US); Harsh R. Patil, Pleasanton, CA (US); Zohair Mehkri, Livermore, CA (US)

(73) Assignee: Flex Ltd., Singapore (SG)

(21) Appl. No.: 18/175,018

(22) Filed: Feb. 27, 2023

(51) Int. Cl. G06F 30/10

(52) U.S. Cl. CPC G06F 30/10

(57) ABSTRACT

Embodiments relate to automated review and analysis of a digital design. Performing an automated review and analysis on a three-dimensional design can comprise collecting data related to the three-dimensional design, performing a pre-processing on the three-dimensional design files and the collected data related to the three-dimensional design and performing a validation of the three-dimensional design based on a plurality of pre-defined design rules and the pre-processing of the three-dimensional design files. An analysis report can be generated based on results of performing the validation of the three-dimensional design.

### FIELD OF THE DISCLOSURE

Embodiments of the present disclosure relate generally to methods and systems for manufacturing design and more particularly to methods and systems for automated review and analysis of a digital design.

### BACKGROUND

Computer-Aided Design (CAD) is the use of computer software to aid in the creation, modification, analysis, or optimization of a design. The output of a CAD application often is in the form of electronic files for print, machining, or other manufacturing operations. Design checks can be performed on these files prior to their use in manufacturing operations. Typically, these design checks are performed manually and not structured. Therefore, these methods come with significant disadvantages. For example, a manual check is time consuming and prone to errors. Most manual checks do not follow a standard analysis process. Inconsistent check results happen due to variation in manual procedures and reliance on engineers' experience. Hence, there is a need for improved methods and systems for automated review and analysis of a digital design.

### BRIEF DESCRIPTION OF THE DRAWINGS

FIG. 1 is a block diagram illustrating elements of an exemplary computing environment in which embodiments of the present disclosure may be implemented.

FIG. 2 is a block diagram illustrating elements of an exemplary computing device in which embodiments of the present disclosure may be implemented.

FIG. 3 is a block diagram illustrating an exemplary environment in which automated design analysis may be performed according to one embodiment of the present disclosure.

FIG. 4 is a flowchart illustrating an exemplary process for performing automated design analysis according to one embodiment of the present disclosure.

FIG. 5 is a flowchart illustrating additional details of an exemplary process for initiating design analysis according to one embodiment of the present disclosure.

FIG. 6 is a flowchart illustrating additional details of an exemplary process for collecting data for a design analysis according to one embodiment of the present disclosure.

FIG. 7 is a flowchart illustrating additional details of an exemplary process for performing pre-processing according to one embodiment of the present disclosure.

FIG. 8 is a flowchart illustrating additional details of an exemplary process for performing a validation on a three-dimensional design according to one embodiment of the present disclosure.

FIG. 9 is a flowchart illustrating additional details of an exemplary process for generating an analysis report according to one embodiment of the present disclosure.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the second reference label.

### DETAILED DESCRIPTION

In the following description, for the purposes of explanation, numerous specific details are set forth in order to provide a thorough understanding of various embodiments disclosed herein. It will be apparent, however, to one skilled in the art that various embodiments of the present disclosure may be practiced without some of these specific details. The ensuing description provides exemplary embodiments only and is not intended to limit the scope or applicability of the disclosure. Furthermore, to avoid unnecessarily obscuring the present disclosure, the preceding description omits a number of known structures and devices. This omission is not to be construed as a limitation of the scopes of the claims. Rather, the ensuing description of the exemplary embodiments will provide those skilled in the art with an enabling description for implementing an exemplary embodiment. It should however be appreciated that the present disclosure may be practiced in a variety of ways beyond the specific detail set forth herein.

While the exemplary aspects, embodiments, and/or configurations illustrated herein show the various components of the system collocated, certain components of the system can be located remotely, at distant portions of a distributed network, such as a Local-Area Network (LAN) and/or Wide-Area Network (WAN) such as the Internet, or within a dedicated system. Thus, it should be appreciated, that the components of the system can be combined in to one or more devices or collocated on a particular node of a distributed network, such as an analog and/or digital telecommunications network, a packet-switch network, or a circuit-switched network. It will be appreciated from the following description, and for reasons of computational efficiency, that the components of the system can be arranged at any location within a distributed network of components without affecting the operation of the system.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire and fiber optics, and may take the form of acoustic or light waves, such as those generated during radio-wave and infra-red data communications.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The term “automatic” and variations thereof, as used herein, refers to any process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

The term “computer-readable medium” as used herein refers to any tangible storage and/or transmission medium that participate in providing instructions to a processor for execution. Such a medium may take many forms, including but not limited to, non-volatile media, volatile media, and transmission media. Non-volatile media includes, for example, Non-Volatile Random-Access Memory (NVRAM), or magnetic or optical disks. Volatile media includes dynamic memory, such as main memory. Common forms of computer-readable media include, for example, a floppy disk, a flexible disk, hard disk, magnetic tape, or any other magnetic medium, magneto-optical medium, a Compact Disk Read-Only Memory (CD-ROM), any other optical medium, punch cards, paper tape, any other physical medium with patterns of holes, a Random-Access Memory (RAM), a Programmable Read-Only Memory (PROM), and Erasable Programable Read-Only Memory (EPROM), a Flash-EPROM, a solid state medium like a memory card, any other memory chip or cartridge, a carrier wave as described hereinafter, or any other medium from which a computer can read. A digital file attachment to e-mail or other self-contained information archive or set of archives is considered a distribution medium equivalent to a tangible storage medium. When the computer-readable media is configured as a database, it is to be understood that the database may be any type of database, such as relational, hierarchical, object-oriented, and/or the like. Accordingly, the disclosure is considered to include a tangible storage medium or distribution medium and prior art-recognized equivalents and successor media, in which the software implementations of the present disclosure are stored.

A “computer readable signal” medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable medium may be transmitted using any appropriate medium, including but not limited to wireless, wireline, optical fiber cable, Radio Frequency (RF), etc., or any suitable combination of the foregoing.

The terms “determine,” “calculate,” and “compute,” and variations thereof, as used herein, are used interchangeably and include any type of methodology, process, mathematical operation or technique.

It shall be understood that the term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the disclosure, brief description of the drawings, detailed description, abstract, and claims themselves.

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Any combination of one or more computer readable medium(s) may be utilized. The computer readable medium may be a computer readable signal medium or a computer readable storage medium.

In yet another embodiment, the systems and methods of this disclosure can be implemented in conjunction with a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device or gate array such as Programmable Logic Device (PLD), Programmable Logic Array (PLA), Field Programmable Gate Array (FPGA), Programmable Array Logic (PAL), special purpose computer, any comparable means, or the like. In general, any device(s) or means capable of implementing the methodology illustrated herein can be used to implement the various aspects of this disclosure. Exemplary hardware that can be used for the disclosed embodiments, configurations, and aspects includes computers, handheld devices, telephones (e.g., cellular, Internet enabled, digital, analog, hybrids, and others), and other hardware known in the art. Some of these devices include processors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein.

Examples of the processors as described herein may include, but are not limited to, at least one of Qualcomm® Snapdragon® 800 and 801, Qualcomm® Snapdragon® 610 and 615 with 4G LTE Integration and 64-bit computing, Apple® A7 processor with 64-bit architecture, Apple® M7 motion coprocessors, Samsung® Exynos® series, the Intel® Core™ family of processors, the Intel® Xeon® family of processors, the Intel® Atom™ family of processors, the Intel Itanium® family of processors, Intel® Core® i5-4670K and i7-4770K 22 nm Haswell, Intel® Core i5-3570K 22 nm Ivy Bridge, the AMD® FX™ family of processors, AMD® FX-4300, FX-6300, and FX-8350 32 nm Vishera, AMD® Kaveri processors, Texas Instruments® Jacinto C6000™ automotive infotainment processors, Texas Instruments® OMAP™ automotive-grade mobile processors, ARM® Cortex™-M processors, ARM® Cortex-A and ARM926EJ-S™ processors, other industry-equivalent processors, and may perform computational functions using any known or future-developed standard, instruction set, libraries, and/or architecture.

In yet another embodiment, the disclosed methods may be readily implemented in conjunction with software using object or object-oriented software development environments that provide portable source code that can be used on a variety of computer or workstation platforms. Alternatively, the disclosed system may be implemented partially or fully in hardware using standard logic circuits or Very Large-Scale Integration (VLSI) design. Whether software or hardware is used to implement the systems in accordance with this disclosure is dependent on the speed and/or efficiency requirements of the system, the particular function, and the particular software or hardware systems or microprocessor or microcomputer systems being utilized.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this disclosure can be implemented as program embedded on personal computer such as an applet, JAVA® or Common Gateway Interface (CGI) script, as a resource residing on a server or computer workstation, as a routine embedded in a dedicated measurement system, system component, or the like. The system can also be implemented by physically incorporating the system and/or method into a software and/or hardware system.

Although the present disclosure describes components and functions implemented in the aspects, embodiments, and/or configurations with reference to particular standards and protocols, the aspects, embodiments, and/or configurations are not limited to such standards and protocols. Other similar standards and protocols not mentioned herein are in existence and are considered to be included in the present disclosure. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present disclosure.

Various additional details of embodiments of the present disclosure will be described below with reference to the figures. While the flowcharts will be discussed and illustrated in relation to a particular sequence of events, it should be appreciated that changes, additions, and omissions to this sequence can occur without materially affecting the operation of the disclosed embodiments, configuration, and aspects.

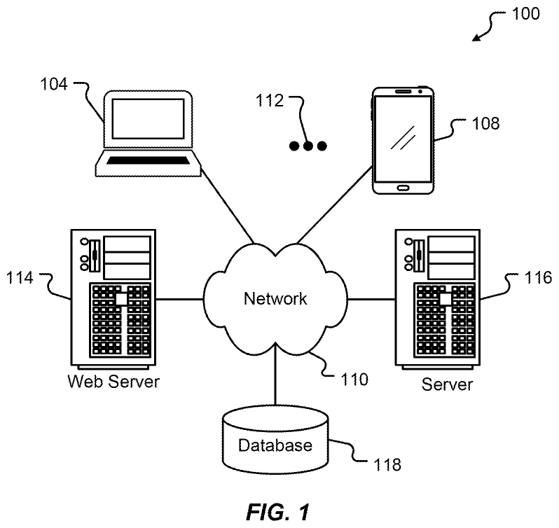

FIG. 1 is a block diagram illustrating elements of an exemplary computing environment in which embodiments of the present disclosure may be implemented. More specifically, this example illustrates a computing environment 100 that may function as the servers, user computers, or other systems provided and described herein. The environment 100 includes one or more user computers, or computing devices, such as a computing device 104, a communication device 108, and/or more 112. The computing devices 104, 108, 112 may include general purpose personal computers (including, merely by way of example, personal computers, and/or laptop computers running various versions of Microsoft Corp.'s Windows® and/or Apple Corp.'s Macintosh® operating systems) and/or workstation computers running any of a variety of commercially-available UNIX® or UNIX-like operating systems. These computing devices 104, 108, 112 may also have any of a variety of applications, including for example, database client and/or server applications, and web browser applications. Alternatively, the computing devices 104, 108, 112 may be any other electronic device, such as a thin-client computer, Internet-enabled mobile telephone, and/or personal digital assistant, capable of communicating via a network 110 and/or displaying and navigating web pages or other types of electronic documents. Although the exemplary computer environment 100 is shown with two computing devices, any number of user computers or computing devices may be supported.

Environment 100 further includes a network 110. The network 110 may can be any type of network familiar to those skilled in the art that can support data communications using any of a variety of commercially-available protocols, including without limitation Session Initiation Protocol (SIP), Transmission Control Protocol/Internet Protocol (TCP/IP), Systems Network Architecture (SNA), Internetwork Packet Exchange (IPX), AppleTalk, and the like. Merely by way of example, the network 110 maybe a Local Area Network (LAN), such as an Ethernet network, a Token-Ring network and/or the like; a wide-area network; a virtual network, including without limitation a Virtual Private Network (VPN); the Internet; an intranet; an extranet; a Public Switched Telephone Network (PSTN); an infra-red network; a wireless network (e.g., a network operating under any of the IEEE 802.9 suite of protocols, the Bluetooth® protocol known in the art, and/or any other wireless protocol); and/or any combination of these and/or other networks.

The system may also include one or more servers 114, 116. In this example, server 114 is shown as a web server and server 116 is shown as an application server. The web server 114, which may be used to process requests for web pages or other electronic documents from computing devices 104, 108, 112. The web server 114 can be running an operating system including any of those discussed above, as well as any commercially-available server operating systems. The web server 114 can also run a variety of server applications, including SIP servers, HyperText Transfer Protocol (secure) (HTTP(s)) servers, FTP servers, CGI servers, database servers, Java servers, and the like. In some instances, the web server 114 may publish operations available operations as one or more web services.

The environment 100 may also include one or more file and or/application servers 116, which can, in addition to an operating system, include one or more applications accessible by a client running on one or more of the computing devices 104, 108, 112. The server(s) 116 and/or 114 may be one or more general purpose computers capable of executing programs or scripts in response to the computing devices 104, 108, 112. As one example, the server 116, 114 may execute one or more web applications. The web application may be implemented as one or more scripts or programs written in any programming language, such as Java™, C, C#®, or C++, and/or any scripting language, such as Perl, Python, or Tool Command Language (TCL), as well as combinations of any programming/scripting languages. The application server(s) 116 may also include database servers, including without limitation those commercially available from Oracle®, Microsoft®, Sybase®, IBM® and the like, which can process requests from database clients running on a computing device 104, 108, 112.

The web pages created by the server 114 and/or 116 may be forwarded to a computing device 104, 108, 112 via a web (file) server 114, 116. Similarly, the web server 114 may be able to receive web page requests, web services invocations, and/or input data from a computing device 104, 108, 112 (e.g., a user computer, etc.) and can forward the web page requests and/or input data to the web (application) server 116. In further embodiments, the server 116 may function as a file server. Although for ease of description, FIG. 1 illustrates a separate web server 114 and file/application server 116, those skilled in the art will recognize that the functions described with respect to servers 114, 116 may be performed by a single server and/or a plurality of specialized servers, depending on implementation-specific needs and parameters. The computer systems 104, 108, 112, web (file) server 114 and/or web (application) server 116 may function as the system, devices, or components described herein.

The environment 100 may also include a database 118. The database 118 may reside in a variety of locations. By way of example, database 118 may reside on a storage medium local to (and/or resident in) one or more of the computers 104, 108, 112, 114, 116. Alternatively, it may be remote from any or all of the computers 104, 108, 112, 114, 116, and in communication (e.g., via the network 110) with one or more of these. The database 118 may reside in a Storage-Area Network (SAN) familiar to those skilled in the art. Similarly, any necessary files for performing the functions attributed to the computers 104, 108, 112, 114, 116 may be stored locally on the respective computer and/or remotely, as appropriate. The database 118 may be a relational database, such as Oracle 20i®, that is adapted to store, update, and retrieve data in response to Structured Query Language (SQL) formatted commands.

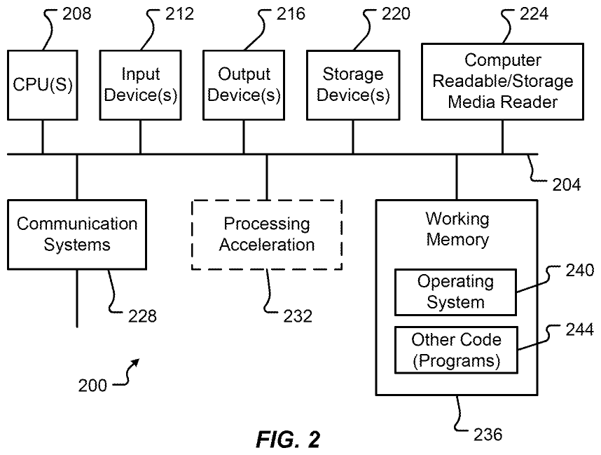

FIG. 2 is a block diagram illustrating elements of an exemplary computing device in which embodiments of the present disclosure may be implemented. More specifically, this example illustrates one embodiment of a computer system 200 upon which the servers, user computers, computing devices, or other systems or components described above may be deployed or executed. The computer system 200 is shown comprising hardware elements that may be electrically coupled via a bus 204. The hardware elements may include one or more Central Processing Units (CPUs) 208; one or more input devices 212 (e.g., a mouse, a keyboard, etc.); and one or more output devices 216 (e.g., a display device, a printer, etc.). The computer system 200 may also include one or more storage devices 220. By way of example, storage device(s) 220 may be disk drives, optical storage devices, solid-state storage devices such as a Random-Access Memory (RAM) and/or a Read-Only Memory (ROM), which can be programmable, flash-updateable and/or the like.

The computer system 200 may additionally include a computer-readable storage media reader 224; a communications system 228 (e.g., a modem, a network card (wireless or wired), an infra-red communication device, etc.); and working memory 236, which may include RAM and ROM devices as described above. The computer system 200 may also include a processing acceleration unit 232, which can include a Digital Signal Processor (DSP), a special-purpose processor, and/or the like.

The computer-readable storage media reader 224 can further be connected to a computer-readable storage medium, together (and, optionally, in combination with storage device(s) 220) comprehensively representing remote, local, fixed, and/or removable storage devices plus storage media for temporarily and/or more permanently containing computer-readable information. The communications system 228 may permit data to be exchanged with a network and/or any other computer described above with respect to the computer environments described herein. Moreover, as disclosed herein, the term “storage medium” may represent one or more devices for storing data, including ROM, RAM, magnetic RAM, core memory, magnetic disk storage mediums, optical storage mediums, flash memory devices and/or other machine-readable mediums for storing information.

The computer system 200 may also comprise software elements, shown as being currently located within a working memory 236, including an operating system 240 and/or other code 244. It should be appreciated that alternate embodiments of a computer system 200 may have numerous variations from that described above. For example, customized hardware might also be used and/or particular elements might be implemented in hardware, software (including portable software, such as applets), or both. Further, connection to other computing devices such as network input/output devices may be employed.

Examples of the processors 208 as described herein may include, but are not limited to, at least one of Qualcomm® Snapdragon® 800 and 801, Qualcomm® Snapdragon® 620 and 615 with 4G LTE Integration and 64-bit computing, Apple® A7 processor with 64-bit architecture, Apple® M7 motion coprocessors, Samsung® Exynos® series, the Intel® Core™ family of processors, the Intel® Xeon® family of processors, the Intel® Atom™ family of processors, the Intel Itanium® family of processors, Intel® Core® i5-4670K and i7-4770K 22 nm Haswell, Intel® Core® i5-3570K 22 nm Ivy Bridge, the AMD® FX™ family of processors, AMD® FX-4300, FX-6300, and FX-8350 32 nm Vishera, AMD® Kaveri processors, Texas Instruments® Jacinto C6000™ automotive infotainment processors, Texas Instruments® OMAP™ automotive-grade mobile processors, ARM® Cortex™-M processors, ARM® Cortex-A and ARM926EJ-S™ processors, other industry-equivalent processors, and may perform computational functions using any known or future-developed standard, instruction set, libraries, and/or architecture.

Embodiments describe an automated system for performing design rule checks and mechanical part & assembly automation readiness checks. The system can use a custom application to start the analysis, input three-dimensional part and assembly files and view the completed analysis result in user readable format. The system can use a design rule database, containing various automation design rules, structured by part type, assembly type, assembly location, feature type, assembly process, automation machine type, material and similar attributes associated with automated manufacturing assembly process and three-dimensional part and assembly files. The system can use another application to perform the three-dimensional design analysis based on pre-defined custom analysis checklist against the design rules in the design rule database previously mentioned. Additional details of such a system are provided in Appendix A submitted herewith and incorporated herein by reference.

Embodiments utilize and establish a structured and automated design rule check, driving each analysis check based on established rule database, perform custom design analysis in three-dimensional part and assemblies, and visualizing the analysis result in user readable formats. Embodiments provide dynamic and standardized process based on product three-dimensional files and defined automation process. Embodiments provide consistent result analysis due to use of dynamic rules database covering multiple three-dimensional part and assembly and automation assembly attributes. Embodiments provide validation of product assembly for automated assemblies using robotic and associated components of automation.

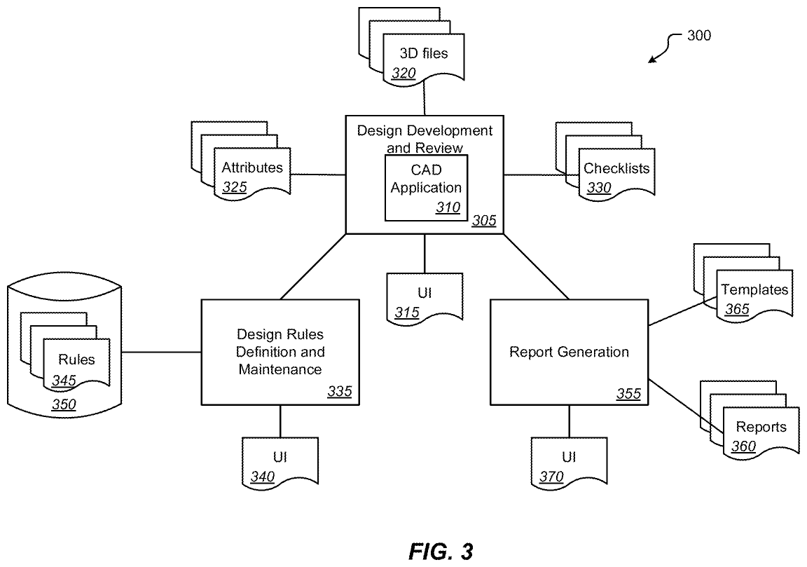

FIG. 3 is a block diagram illustrating an exemplary environment in which automated design analysis may be performed according to one embodiment of the present disclosure. As illustrated in this example, the environment 300 can include a design development and review component 305. The design development and review component can be any one or more servers and/or other computing devices as described above. The design development and review component can execute a three-dimensional Computer-Aided Design (CAD) application 310. As known in the art, the three-dimensional CAD application can present a user interface 315 through which a user may define, view, modify, etc. any number of digital designs defined in a set of three-dimensional design files 320. Similarly, the three-dimensional CAD application may generate and/or maintain a set of attributes for parts, assemblies, and/or features of the designs as well as one or more checklists 330 for specifications and/or requirements related to the design.

The environment can also include a design rules definition and maintenance component 335. The design rules definition and maintenance component 335 can comprise one or more servers and/or other computing devices as described above. While shown here as separate from the design development and review component 305 for the sake of illustration, the design rules definition and maintenance component 335 may be implemented on the same or different physical and/or virtual machines as the design development and review component 305. The design rules definition and maintenance component 335 can present a user interface 340 through which a user can define a set of design rules 345 maintained by the design rules definition and maintenance component 335 in a rules database 350.

Generally speaking, an automated review and analysis on a three-dimensional design can be performed by initiating, by the design development and review component 305, a review of a plurality of three-dimensional CAD files 320 defining the three-dimensional design. The design development and review component 305 can collect data related to the three-dimensional design. This data can be collected for a new analysis job or from one or more previous analysis jobs. The design development and review component 305 can then perform a pre-processing on the plurality of three-dimensional CAD files 320 and the collected data related to the three-dimensional design. This pre-processing can comprise standardizing naming of various parts and assemblies of the design, assigning attributes to those parts and assemblies, and defining a processes for assembling the design. The design development and review component 305 can performing a validation of the three-dimensional design based on a plurality of pre-defined design rules 345 maintained by the design rules definition and maintenance component 335 and the pre-processing of the plurality of three-dimensional CAD files. Performing the validation can comprise checking the design against one or more predefined checklists 330, applying the design rules 345, and/or performing other checks on the design in the 3D application to generate a set of results.

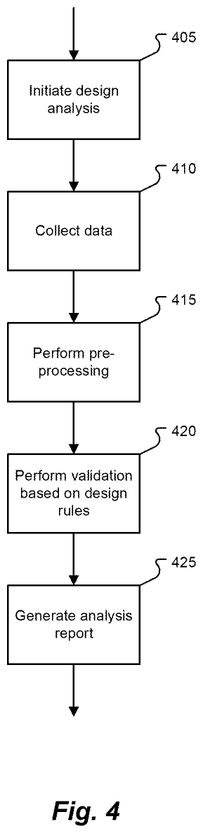

The results can then be exported by the design development and review component 305 to a report generation component 355 of the environment 300. The report generation component 355 can comprise one or more servers and/or other computing devices as described above. While shown here as separate from the design development and review component 305 and design rules definition and maintenance component 335 for the sake of illustration, the report generation component 355 may be implemented on the same or different physical and/or virtual machines as the design development and review component 305 and/or design rules definition and maintenance component 335. Regardless of the exact implementation, the report generation component 355 can generate an analysis report based on the exported results of performing the validation of the three-dimensional design from the design development and review component 305. In some cases, the analysis report can be generated based on a selected report design, e.g., one of a set of report templates 365 defined and maintained by the report generation component 355. In some cases, the generated report can be presented in graphical or other user interface 370 for review by one or more users. Additional details of exemplary processes for performing an automated review and analysis on a three-dimensional design will be described below with reference to FIGS. 4-9.

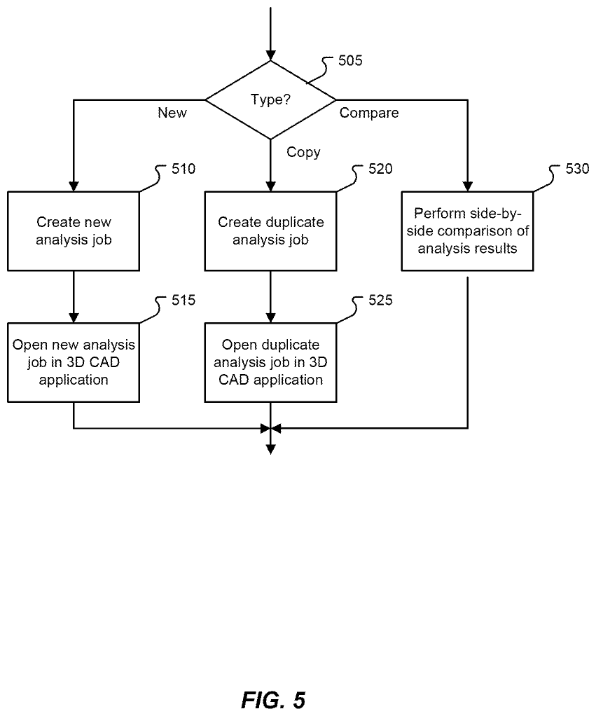

FIG. 4 is a flowchart illustrating an exemplary process for performing automated design analysis according to one embodiment of the present disclosure. As illustrated in this example, performing an automated review and analysis on a three-dimensional design can begin with initiating 405 a review of a plurality of three-dimensional CAD files defining the three-dimensional design. Generally speaking, initiating 405 the review and analysis can comprise generating an analysis job and/or collecting results of a previous review and analysis and launching a three-dimensional CAD application to execute the review and analysis. Additional details of an exemplary process for initiating 405 the review of the three-dimensional design will be described below with reference to FIG. 5.

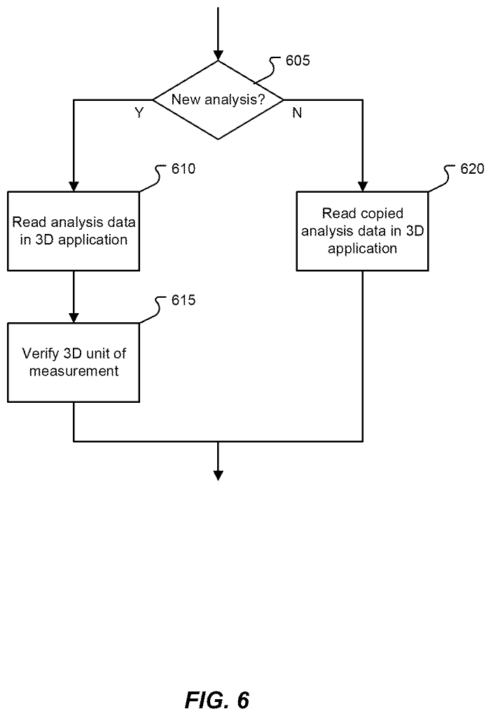

Data related to the three-dimensional design can be collected 410. Generally speaking, this data can be collected 410 for a new analysis job or from one or more previous analysis jobs. Additional details of an exemplary process for collecting 410 data related to the three-dimensional design will be described below with reference to FIG. 6.

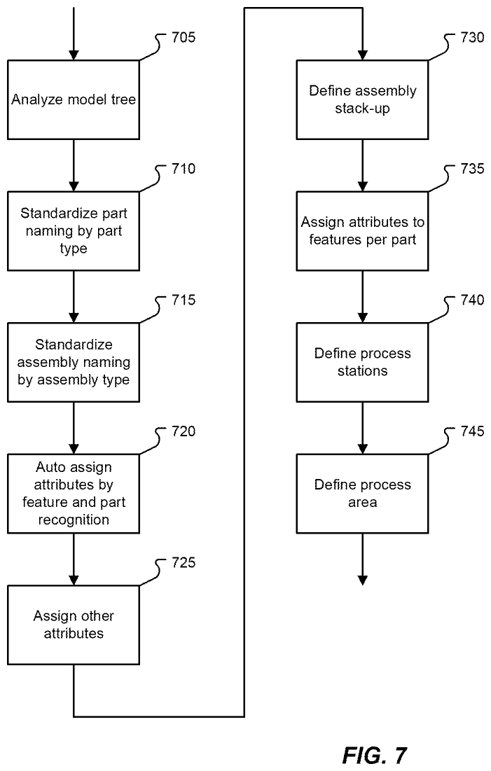

A pre-processing can be performed 415 on the plurality of three-dimensional CAD files and the collected data related to the three-dimensional design. Generally speaking, this pre-processing can comprise standardizing naming of various parts and assemblies of the design, assigning attributes to those parts and assemblies, and defining a processes for assembling the design. Additional details of an exemplary process for performing 415 preprocessing on the plurality of three-dimensional CAD files will be described below with reference to FIG. 7.

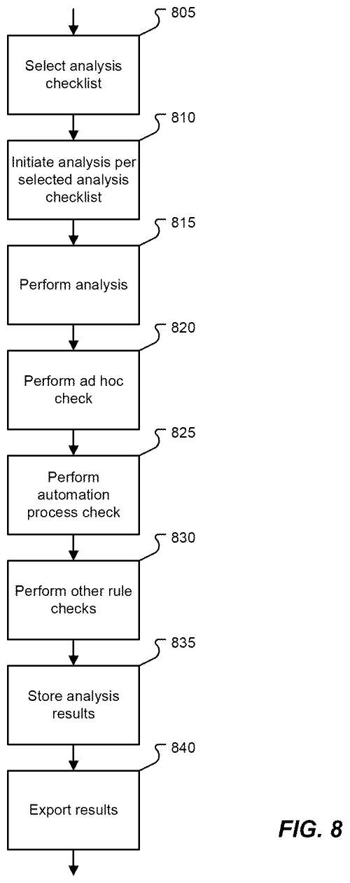

A validation of the three-dimensional design can then be performed 420 based on a plurality of pre-defined design rules and the pre-processing of the plurality of three-dimensional CAD files. Generally speaking, performing 420 the validation can comprise checking the design against one or more predefined checklists, applying the design rules, and/or performing other checks on the design in the 3D application to generate a set of results. Additional details of an exemplary process for performing 420 the validation of the three-dimensional design will be described below with reference to FIG. 8.

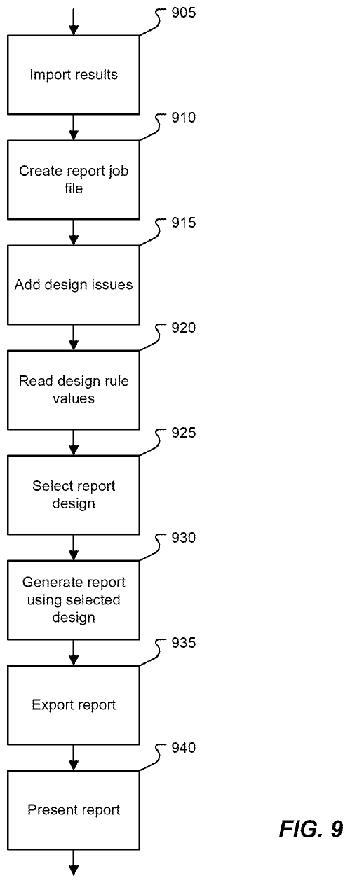

An analysis report can then be generated 425 based on the results of performing 420 the validation of the three-dimensional design. In some cases, the analysis report can be generated 425 based on a selected report design, e.g., a report template. Additional details of an exemplary process for generating 425 the analysis report will be described below with reference to FIG. 9.

FIG. 5 is a flowchart illustrating additional details of an exemplary process for initiating design analysis according to one embodiment of the present disclosure. As illustrated in this example, initiating the review of the plurality of three-dimensional CAD files can comprise determining 505 a review type for the automated review and analysis on the three-dimensional design. The review type can be one of a new review, a copy of a previous review and analysis, or a comparison of two previous reviews and analyses. In response to determining 505 the review type for the automated review and analysis on the three-dimensional design is a new review and analysis, a new analysis job can be created 510 and opened 515 in the three-dimensional CAD application. In response to determining 505 the review type for the automated review and analysis on the three-dimensional design is a copy of a previous automated review and analysis on the three-dimensional design, a duplicate analysis job can be created 520 based on the previous automated review and analysis on the three-dimensional design and the duplicate analysis job can be opened 525 in the three-dimensional CAD application. In response to determining 505 the review type for the automated review and analysis on the three-dimensional design is a comparison of two previous automated reviews and analyses on the three-dimensional design, a side-by-side comparison of results from the two previous automated reviews and analyses on the three-dimensional design can be performed in the three-dimensional CAD application.

FIG. 6 is a flowchart illustrating additional details of an exemplary process for collecting data for a design analysis according to one embodiment of the present disclosure. As illustrated in this example, collecting the data related to the three-dimensional design can comprise determining 605 whether the review type for the automated review and analysis is a new review. In response to determining 605 the review type for the automated review and analysis on the three-dimensional design is a new review and analysis a set of analysis data for the new analysis job can be read 610 and a three-dimensional unit of measurement for the new analysis job can be verified 615. In response to determining 605 the review type for the automated review and analysis on the three-dimensional design is not a new review, i.e., it is a copy of a previous automated review and analysis on the three-dimensional design or a comparison of two previous automated reviews and analyses on the three-dimensional design, a set of analysis data for the previous automated review and analysis, or two reviews and analyses, can be read 620.

FIG. 7 is a flowchart illustrating additional details of an exemplary process for performing pre-processing according to one embodiment of the present disclosure. As illustrated in this example, performing the pre-processing on the plurality of three-dimensional CAD files and the collected data related to the three-dimensional design can comprise analyzing 705 a model tree for the three-dimensional design and standardizing 710 part naming for a plurality of parts in the three-dimensional design. The part naming for the plurality of parts can be standardized based on a part type for each part of the plurality of parts. Assembly naming for a plurality of assemblies in the three-dimensional design can also be standardized 715, e.g., based on an assembly type for each assembly of the plurality of assemblies.

One or more automatic attributes can be assigned 720 to each of one or more features of the three-dimensional design of one or more parts of the three-dimensional design based on recognition of the one or more features or one or more parts. One or more additional attributes can also be assigned 725 to the three-dimensional design.

An assembly stack-up for the three-dimensional design can then be defined 730 in the three-dimensional CAD application and one or more attributes can be assigned 735 to one or more features of one or more parts. A plurality of process stations for assembly of the three-dimensional design can then also be defined 740 in the three-dimensional application. A process area for assembly of the three-dimensional design can then be defined 745 in the three-dimensional CAD application based on the plurality of process stations.

FIG. 8 is a flowchart illustrating additional details of an exemplary process for performing a validation on a three-dimensional design according to one embodiment of the present disclosure. As illustrated in this example, performing the validation of the three-dimensional design based on the plurality of pre-defined design rules and the pre-processing of the plurality of three-dimensional CAD files can comprise selecting 805, from a plurality of predefined checklists, an analysis checklist for the validation of the three-dimensional design.

An analysis on the pre-processed CAD files can then be initiated 810 and performed 815 in the three-dimensional CAD application based on the selected analysis checklist. Generally speaking, this can comprise determining whether each checklist item is satisfied in the design as represented in the pre-processed CAD files. In some cases, an ad hoc check may also be performed 820 on the pre-processed CAD files.

An automation process check can then be performed 825 on the pre-processed CAD files based on the plurality of pre-defined design rules. That is, automated checks can be executed in the three-dimensional CAD application by applying the pre-defined design rules to the designed as defined in the pre-processed CAD files to determine, for example, whether required elements are present, certain other conditions are satisfied, etc. to determine whether the design or a portion of the design passes or fails the requirements defined in the rules. In some cases, one or more additional rule checks can be performed 830 on the pre-processed CAD files.

A set of results for the validation of the three-dimensional design can then be stored 835 for future use, e.g., for review, as the basis of a duplicate, future review, for comparison to another review, etc. Additionally, or alternatively, the set of results for the validation of the three-dimensional design can be exported, e.g., to another application to generate a report, display results in a user interface, etc.

FIG. 9 is a flowchart illustrating additional details of an exemplary process for generating an analysis report according to one embodiment of the present disclosure. As illustrated in this example, generating the analysis report based on results of performing the validation of the three-dimensional design can comprise importing 905 the set of results for the validation of the three-dimensional design and creating 910 a report job file for the analysis report based on the imported set of results for the validation of the three-dimensional design. One or more design issues can be added 915 to the report job file based on the imported set of results for the validation of the three-dimensional design. A set of values for the plurality of pre-defined design rules can also be read 920. A report design can be selected 925 from a plurality of pre-defined report designs, e.g., from a set of templates or similar predefined formats for different reports. The analysis report generated 930 from the report job file and the set of values for the plurality of pre-defined design rules using the selected report design. The generated analysis report can then be exported 935, e.g., to another system, saved in a file, etc. Additionally, or alternatively, the generated analysis report can be present 940 to one or more users, e.g., in a graphical or other user interface.

The present disclosure, in various aspects, embodiments, and/or configurations, includes components, methods, processes, systems, and/or apparatus substantially as depicted and described herein, including various aspects, embodiments, configurations embodiments, sub-combinations, and/or subsets thereof. Those of skill in the art will understand how to make and use the disclosed aspects, embodiments, and/or configurations after understanding the present disclosure. The present disclosure, in various aspects, embodiments, and/or configurations, includes providing devices and processes in the absence of items not depicted and/or described herein or in various aspects, embodiments, and/or configurations hereof, including in the absence of such items as may have been used in previous devices or processes, e.g., for improving performance, achieving ease and/or reducing cost of implementation.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as a separate preferred embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A method for performing an automated review and analysis on a three-dimensional design, the method comprising:
initiating, by a processor of a design development and review system, a review of a plurality of three-dimensional Computer Aided Design (CAD) files defining the three-dimensional design;
collecting, by the processor of the design development and review system, data related to the three-dimensional design;
performing, by the processor of the design development and review system, a pre-processing on the plurality of three-dimensional CAD files and the collected data related to the three-dimensional design;
performing, by the processor of the design development and review system, a validation of the three-dimensional design based on a plurality of pre-defined design rules and the pre-processing of the plurality of three-dimensional CAD files; and
generating, by the processor of the design development and review system, an analysis report based on results of performing the validation of the three-dimensional design.

2. The method of claim 1, wherein initiating the review of the plurality of three-dimensional CAD files comprises:
determining a review type for the automated review and analysis on the three-dimensional design; and
in response to determining the review type for the automated review and analysis on the three-dimensional design is a new review and analysis, creating a new analysis job and opening the new analysis job in a three-dimensional CAD application.

3. The method of claim 2, further comprising in response to determining the review type for the automated review and analysis on the three-dimensional design is a copy of a previous automated review and analysis on the three-dimensional design, creating a duplicate analysis job based on the previous automated review and analysis on the three-dimensional design and opening the duplicate analysis job in the three-dimensional CAD application.

4. The method of claim 3, further comprising in response to determining the review type for the automated review and analysis on the three-dimensional design is a comparison of two previous automated reviews and analyses on the three-dimensional design, performing a side-by-side comparison of results from the two previous automated reviews and analyses on the three-dimensional design.

5. The method of claim 4, wherein collecting the data related to the three-dimensional design further comprises, in response to determining the review type for the automated review and analysis on the three-dimensional design is a new review and analysis:
reading a set of analysis data for the new analysis job; and
verifying a three-dimensional unit of measurement for the new analysis job.

6. The method of claim 5, wherein collecting the data related to the three-dimensional design further comprises, in response to determining the review type for the automated review and analysis on the three-dimensional design is a copy of a previous automated review and analysis on the three-dimensional design, reading a set of analysis data for the previous automated review and analysis.

7. The method of claim 5, wherein collecting the data related to the three-dimensional design further comprises, in response to determining the review type for the automated review and analysis on the three-dimensional design is a comparison of two previous automated reviews and analyses on the three-dimensional design, reading a set of analysis data for the previous automated reviews and analyses.

8. The method of claim 1, wherein performing the pre-processing on the plurality of three-dimensional CAD files and the collected data related to the three-dimensional design comprises:
analyzing a model tree for the three-dimensional design;
standardizing part naming for a plurality of parts in the three-dimensional design, wherein the part naming for the plurality of parts is standardized based on a part type for each part of the plurality of parts;
standardizing assembly naming for a plurality of assemblies in the three-dimensional design, wherein the assembly naming for the plurality of assemblies is standardized based on an assembly type for each assembly of the plurality of assemblies;
assigning one or more automatic attributes to each of one or more features of the three-dimensional design of one or more parts of the three-dimensional design based on recognition of the one or more features or one or more parts;
assigning one or more additional attributes to the three-dimensional design;
defining an assembly stack-up for the three-dimensional design;
assigning one or more attributes to one or more features of one or more parts;
defining a plurality of process stations for assembly of the three-dimensional design; and
defining a process area for assembly of the three-dimensional design based on the plurality of process stations.

9. The method of claim 1, wherein performing the validation of the three-dimensional design based on the plurality of pre-defined design rules and the pre-processing of the plurality of three-dimensional CAD files further comprises:
selecting, from a plurality of predefined checklists, an analysis checklist for the validation of the three-dimensional design;
performing an analysis on the pre-processed CAD files based on the selected analysis checklist;
performing an ad hoc check on the pre-processed CAD files;
performing an automation process check on the pre-processed CAD files based on the plurality of pre-defined design rules;
performing one or more additional rule checks on the pre-processed CAD files;
storing a set of results for the validation of the three-dimensional design; and
exporting the set of results for the validation of the three-dimensional design.

10. The method of claim 8, wherein generating the analysis report based on results of performing the validation of the three-dimensional design further comprises:
importing the set of results for the validation of the three-dimensional design;
creating a report job file for the analysis report based on the imported set of results for the validation of the three-dimensional design;
adding one or more design issues to the report job file based on the imported set of results for the validation of the three-dimensional design;
reading a set of values for the plurality of pre-defined design rules;
selecting a report design from a plurality of pre-defined report designs;
generating the analysis report from the report job file and the set of values for the plurality of pre-defined design rules using the selected report design; and
exporting the generated analysis report.

11. A system comprising:
a processor; and
a memory coupled with and readable by the processor and storing therein a set of instructions which, when executed by the processor, causes the processor to perform an automated review and analysis on a three-dimensional design by:
initiating a review of a plurality of three-dimensional Computer Aided Design (CAD) files defining the three-dimensional design;
collecting data related to the three-dimensional design;
performing a pre-processing on the plurality of three-dimensional CAD files and the collected data related to the three-dimensional design;
performing a validation of the three-dimensional design based on a plurality of pre-defined design rules and the pre-processing of the plurality of three-dimensional CAD files; and
generating an analysis report based on results of performing the validation of the three-dimensional design.

12. The system of claim 11, wherein initiating the review of the plurality of three-dimensional CAD files comprises:
determining a review type for the automated review and analysis on the three-dimensional design;
in response to determining the review type for the automated review and analysis on the three-dimensional design is a new review and analysis, creating a new analysis job and opening the new analysis job in a three-dimensional CAD application;
in response to determining the review type for the automated review and analysis on the three-dimensional design is a copy of a previous automated review and analysis on the three-dimensional design, creating a duplicate analysis job based on the previous automated review and analysis on the three-dimensional design and opening the duplicate analysis job in the three-dimensional CAD application; and
in response to determining the review type for the automated review and analysis on the three-dimensional design is a comparison of two previous automated reviews and analyses on the three-dimensional design, performing a side-by-side comparison of results from the two previous automated reviews and analyses on the three-dimensional design.

13. The system of claim 12, wherein collecting the data related to the three-dimensional design further comprises:
in response to determining the review type for the automated review and analysis on the three-dimensional design is a new review and analysis, reading a set of analysis data for the new analysis job, and verifying a three-dimensional unit of measurement for the new analysis job;
in response to determining the review type for the automated review and analysis on the three-dimensional design is a copy of a previous automated review and analysis on the three-dimensional design, reading a set of analysis data for the previous automated review and analysis; and
in response to determining the review type for the automated review and analysis on the three-dimensional design is a comparison of two previous automated reviews and analyses on the three-dimensional design, reading a set of analysis data for the previous automated reviews and analyses.

14. The system of claim 11, wherein performing the pre-processing on the plurality of three-dimensional CAD files and the collected data related to the three-dimensional design comprises:
analyzing a model tree for the three-dimensional design;
standardizing part naming for a plurality of parts in the three-dimensional design, wherein the part naming for the plurality of parts is standardized based on a part type for each part of the plurality of parts;
standardizing assembly naming for a plurality of assemblies in the three-dimensional design, wherein the assembly naming for the plurality of assemblies is standardized based on an assembly type for each assembly of the plurality of assemblies;
assigning one or more automatic attributes to each of one or more features of the three-dimensional design of one or more parts of the three-dimensional design based on recognition of the one or more features or one or more parts;
assigning one or more additional attributes to the three-dimensional design;
defining an assembly stack-up for the three-dimensional design;
assigning one or more attributes to one or more features of one or more parts;
defining a plurality of process stations for assembly of the three-dimensional design; and
defining a process area for assembly of the three-dimensional design based on the plurality of process stations.

15. The system of claim 11, wherein performing the validation of the three-dimensional design based on the plurality of pre-defined design rules and the pre-processing of the plurality of three-dimensional CAD files further comprises:
selecting, from a plurality of predefined checklists, an analysis checklist for the validation of the three-dimensional design;
performing an analysis on the pre-processed CAD files based on the selected analysis checklist;
performing an ad hoc check on the pre-processed CAD files;
performing an automation process check on the pre-processed CAD files based on the plurality of pre-defined design rules;
performing one or more additional rule checks on the pre-processed CAD files;
storing a set of results for the validation of the three-dimensional design; and
exporting the set of results for the validation of the three-dimensional design.

16. The method of claim 15, wherein generating the analysis report based on results of performing the validation of the three-dimensional design further comprises:
importing the set of results for the validation of the three-dimensional design;
creating a report job file for the analysis report based on the imported set of results for the validation of the three-dimensional design;
adding one or more design issues to the report job file based on the imported set of results for the validation of the three-dimensional design;
reading a set of values for the plurality of pre-defined design rules;
selecting a report design from a plurality of pre-defined report designs;
generating the analysis report from the report job file and the set of values for the plurality of pre-defined design rules using the selected report design; and
exporting the generated analysis report.

17. A non-transitory, computer readable medium comprising a set of instructions which, when executed by a processor, causes the processor to perform an automated review and analysis on a three-dimensional design by:
initiating a review of a plurality of three-dimensional Computer Aided Design (CAD) files defining the three-dimensional design;
collecting data related to the three-dimensional design;
performing a pre-processing on the plurality of three-dimensional CAD files and the collected data related to the three-dimensional design;
performing a validation of the three-dimensional design based on a plurality of pre-defined design rules and the pre-processing of the plurality of three-dimensional CAD files; and
generating an analysis report based on results of performing the validation of the three-dimensional design.

18. The non-transitory, computer readable medium of claim 17, wherein performing the pre-processing on the plurality of three-dimensional CAD files and the collected data related to the three-dimensional design comprises:
analyzing a model tree for the three-dimensional design;
standardizing part naming for a plurality of parts in the three-dimensional design, wherein the part naming for the plurality of parts is standardized based on a part type for each part of the plurality of parts;
standardizing assembly naming for a plurality of assemblies in the three-dimensional design, wherein the assembly naming for the plurality of assemblies is standardized based on an assembly type for each assembly of the plurality of assemblies;
assigning one or more automatic attributes to each of one or more features of the three-dimensional design of one or more parts of the three-dimensional design based on recognition of the one or more features or one or more parts;
assigning one or more additional attributes to the three-dimensional design;
defining an assembly stack-up for the three-dimensional design;
assigning one or more attributes to one or more features of one or more parts;
defining a plurality of process stations for assembly of the three-dimensional design; and
defining a process area for assembly of the three-dimensional design based on the plurality of process stations.

19. The non-transitory, computer readable medium of claim 17, wherein performing the validation of the three-dimensional design based on the plurality of pre-defined design rules and the pre-processing of the plurality of three-dimensional CAD files further comprises:
selecting, from a plurality of predefined checklists, an analysis checklist for the validation of the three-dimensional design;
performing an analysis on the pre-processed CAD files based on the selected analysis checklist;
performing an ad hoc check on the pre-processed CAD files;
performing an automation process check on the pre-processed CAD files based on the plurality of pre-defined design rules;
performing one or more additional rule checks on the pre-processed CAD files;
storing a set of results for the validation of the three-dimensional design; and
exporting the set of results for the validation of the three-dimensional design.

20. The non-transitory, computer readable medium of claim 19, wherein generating the analysis report based on results of performing the validation of the three-dimensional design further comprises:
importing the set of results for the validation of the three-dimensional design;
creating a report job file for the analysis report based on the imported set of results for the validation of the three-dimensional design;
adding one or more design issues to the report job file based on the imported set of results for the validation of the three-dimensional design;
reading a set of values for the plurality of pre-defined design rules;
selecting a report design from a plurality of pre-defined report designs;
generating the analysis report from the report job file and the set of values for the plurality of pre-defined design rules using the selected report design; and
exporting the generated analysis report.
